(19) United States
(12) Patent Application Publication
(10) Pub. No.: US 2008/0284537 A1
(43) Pub. Date: Nov. 20, 2008

(54) Impedance Matching Network, and Plasma Processing Apparatus Using Such Impedance Matching Network

(76) Inventor: Sumifusa Ikenouchi, Hojo-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/665,974

(22) PCT Filed: Oct. 31, 2005
(86) PCT No.: PCT/JP05/20333

§ 371 Date: Apr. 23, 2007

(30) Foreign Application Priority Data
Nov. 10, 2004 (JP) 2004-326654

(51) Int. Cl. H03H 7/40

(52) U.S. Cl. 333/17.3; 315/111.21

(57) ABSTRACT

Provided is an impedance matching network having: an amplitude-adjusting variable capacitor and a phase-adjusting variable capacitor that are positioned between an input terminal and an output terminal, matching being achieved by adjustment of values of the variable capacitors; a first capacitor connected in series to one of the variable capacitors; a first switch connected in parallel to the one of the variable capacitors; and a unit operable to a) keep the first switch to an ON state while the input terminal does not receive RF power, and b) bring the first switch to an OFF state immediately after an initial start-up of a load connected to the output terminal after the input terminal has started to receive RF power.

### TECHNICAL FIELD

The present invention relates to an impedance matching network employed for such purposes as supplying radio frequency (RF) power to a plasma processing apparatus, where the plasma processing apparatus is used in manufacturing semiconductor products, and the like. The present invention also relates to a plasma processing apparatus that uses such an impedance matching network.

### BACKGROUND ART

In recent years, plasma processing apparatuses have become large in size, and are required to perform fine processing more than ever. Higher performance is also requested of an automatic impedance matching network, which is provided between a plasma processing apparatus and an RF generator that supplies an RF power to this plasma processing apparatus. Some plasma processing completes in a very short time (e.g. 10 seconds). If matching takes 1-2 seconds in such short plasma processing, wafers, being products, will be subjected to considerable damages during this period of 1-2 seconds.

In light of this, there is a demand for increasing the matching speed and for stabilizing the degree of matching. There is already a publicly-known technology that enables fine control in response to impedance fluctuations in a plasma chamber, as is disclosed by Japanese Laid-open patent application No. 2003-249400 for example. This patent application realizes such fine control by providing an impedance conversion circuit between a RF generator and an impedance matching network, in a system where the impedance matching network is provided between the RF generator and the plasma chamber.

Many of conventional automatic impedance matching networks are an L-type matching circuit, and so adopt a vacuum variable capacitor that is driven by a motor. Once the impedance matching is lost in such an automatic impedance matching network, its phase/amplitude detector detects change in phase and amplitude, according to which the motor is driven to adjust the vacuum capacitor.

However the conventional apparatus disclosed by this patent application, although enabling the fine control in response to the impedance fluctuations in the plasma chamber, has not realized improvement in the matching speed or in the degree of matching. In addition, so as to realize high performance on the conventional automatic impedance matching network, various apparatuses become necessary. For example, a large driving motor and a large high-speed hydraulic driving apparatus are necessary so as to increase the matching speed, and a high performance computer is necessary so as to realize the high degree of matching. These apparatuses incur extremely large expenses, and so the conventional automatic impedance matching networks have not yet been in actual use.

In view of this, the object of the present invention is to provide an impedance matching network having an increased matching speed and an improved degree of matching, and also to bring to practical use at a reasonable cost, the impedance matching network and a plasma processing apparatus that uses the impedance matching network.

### DISCLOSURE OF THE INVENTION

So as to achieve the above-stated object, the present invention provides an impedance matching network having: an amplitude-adjusting variable capacitor and a phase-adjusting variable capacitor that are positioned between an input terminal and an output terminal, matching being achieved by adjustment of values of the variable capacitors; a first capacitor connected in series to one of the variable capacitors; a first switch connected in parallel to the one of the variable capacitors; and a unit operable to a) keep the first switch to an ON state while the input terminal does not receive RF power, and b) bring the first switch to an OFF state immediately after an initial start-up of a load connected to the output terminal after the input terminal has started to receive RF power.

In addition to the above-stated structure, the impedance matching network may further have: a second capacitor connected in series to the other of the variable capacitors; a second switch connected in parallel to the other of the variable capacitors; and a unit operable to a) keep the second switch to an ON state while the input terminal does not receive RF power, and b) bring the second switch to an OFF state immediately after the initial start-up of the load connected to the output terminal after the input terminal has started to receive RF power.

In addition to the above-stated structure, the impedance matching network may have a circuit operable to lower impedance, the circuit being positioned between the input terminal and an impedance matching circuit that is mainly composed of the variable capacitors.

In the impedance matching network having the above-stated structure, the first switch and the second switch may be simultaneously brought to an OFF state.

The present invention also provides a plasma processing apparatus having: an impedance matching network including an amplitude-adjusting variable capacitor and a phase-adjusting variable capacitor that are positioned between an input terminal and an output terminal; an RF generator connected to the input terminal; and a plasma chamber connected, as a load, to the output terminal, matching between the RF generator and the plasma chamber being achieved by adjustment of values of the variable capacitors, where the impedance matching network includes: a first capacitor connected in series to one of the variable capacitors; a first switch connected in parallel to the one of the variable capacitors; and a unit operable to a) keep the first switch to an ON state while the input terminal does not receive RF power, and b) bring the first switch to an OFF state immediately after ignition of the plasma chamber after the input terminal has started to receive RF power.

In addition to the above-stated structure, the plasma processing apparatus may further have: a second capacitor connected in series to the other of the variable capacitors; a second switch connected in parallel to the other of the variable capacitors; and a unit operable to a) keep the second switch to an ON state while the input terminal does not receive RF power, and b) bring the second switch to an OFF state immediately after the ignition of the plasma chamber after the input terminal has started to receive RF power.

In addition to the above-stated structure, the plasma processing apparatus may have: a circuit operable to lower impedance, the circuit being positioned between the input terminal and an impedance matching circuit that is mainly composed of the variable capacitors.

In the plasma processing apparatus having the above-stated structure, the first switch and the second switch may be simultaneously brought to an OFF state.

In the plasma processing apparatus having the above-stated structure, the variable capacitors may be pre-set to respective values before application of RF power to the input terminal, the values being such that impedance matching between the RF generator and the plasma chamber is achieved.

According to the impedance matching network and the plasma processing apparatus of the present invention, it becomes possible to increase the matching speed, with a simple structure in which at least one of the phase-adjusting variable capacitor and the amplitude-adjusting variable capacitor is connected in series to a capacitor and is connected in parallel to a switch, and it becomes possible to achieve a more favorable level of matching, with a simple structure in which a circuit that lowers impedance is provided between the input terminal and the impedance matching network.

### BRIEF DESCRIPTION OF THE DRAWINGS

FIG. 1 is a schematic circuit diagram showing a plasma processing apparatus that includes an impedance matching network of one embodiment of the present invention.

FIG. 2 is a smith chart representing a conventional case, shown to explain the impedance matching network.

FIG. 3 is a smith chart shown to explain the impedance matching network.

FIG. 4 is a smith chart shown to explain explaining the impedance matching network.

FIG. 5 is a smith chart shown to explain the impedance matching network.

FIG. 6 is a schematic circuit diagram relating to another embodiment.

FIG. 7 is a smith chart shown to explain the impedance matching network.

FIG. 8 is a smith chart shown to explain the impedance matching network of FIG. 1.

FIG. 9A is a schematic circuit diagram showing simulation relating to a conventional impedance matching network and FIG. 9B is a schematic circuit diagram showing simulation relating to the impedance matching network of the present invention.

FIG. 10 shows a result of simulation performed using the circuit of FIG. 9.

FIG. 11 shows graphs created based on the result shown in FIG. 10.

FIG. 12 shows characteristics relating to a conventional impedance matching network.

FIG. 13 shows characteristics relating to the impedance matching network of the present invention.

### BEST MODE FOR CARRYING OUT THE INVENTION

The following describes one embodiment of the present invention, with reference to the drawings.

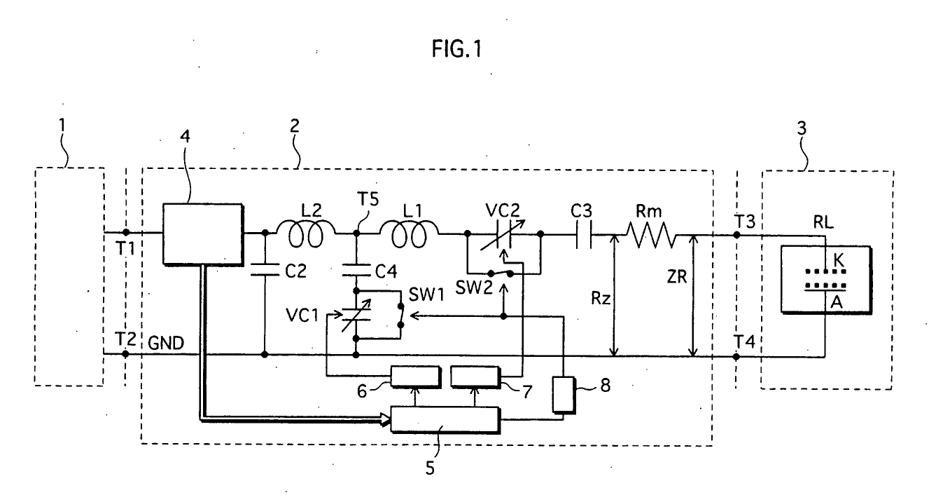

FIG. 1 is a schematic circuit diagram showing a plasma processing apparatus that includes an impedance matching network of one embodiment of the present invention. As shown in FIG. 1, radio frequency (RF) power (13.5 MHz) outputted from an RF generator 1 is supplied to a plasma chamber 3 via an impedance matching network 2. The RF generator 1 and the impedance matching network 2 are connected to each other by a coaxial cable. The impedance matching network 2 and the plasma chamber 3 are in direct connection with each other (by means of a coaxial cable in the case of 500 W or lower, and by means of a bar such as a copper plate in the case of 500 W or above). In FIG. 1, T1 and T2 are respectively a junction point (input terminal) at the side of the RF generator 1, and T3 and T4 are respectively a junction point (output terminal) at the side of the plasma chamber 3. T2 and T4 are respectively to the earth (GND).

The impedance matching network 2 adopts a general LC circuit. The concrete circuit structure of the impedance matching network 2 is described as follows. The impedance matching network 2 is provided with a phase/amplitude detector 4. An end of a coil L2 and an end of a capacitor C2 are connected to this detector 4. The other end of the capacitor C2 is grounded to the earth. The other end of the coil L2 is connected to: one end of a coil L1; and one end of a capacitor C4 connected in series to a variable capacitor VC1. The other end of the variable capacitor VC1 is grounded to earth. In addition, a switch SW1 is connected in parallel with the variable capacitor VC1. The other end of the coil L1 is connected to one end of a capacitor C3 via a parallel circuit between a variable capacitor VC2 and a switch SW2. The other end of the capacitor C3 is connected to the junction point T3 via a resistance Rm. Note that the resistance Rm is a real resistance representing all the resistances within the impedance matching network 2.

The impedance matching network 2 is provided with a control unit 5 to which information of phase and amplitude is given from the phase/amplitude detector 4. The impedance matching network 2 is also provided with motors 6 and 7 that variably control the variable capacitors VC1 and VC2, respectively. The control unit 5 controls the motors 6 and 7.

When there is no power output from the RF generator 1, the switches SW1 and SW2 are in the ON state. The switches SW1 and SW2 are to be brought to the OFF state when the control unit 5 detects ignition at the plasma chamber 3 after starting of power output. So as to realize such a structure, a delay circuit 8 is provided to realize delay of about 0.1 second. The delay circuit 8 specifically brings the switches SW1 and SW2 to the OFF state when 0.1 second has elapsed after starting of power output, interpreting that the plasma chamber 3 started to ignite after this period of 0.1 second. Here, the signal to be given to the delay circuit 8 is not limited to the signal from the control unit 5, but may be the signal outputted after detecting the throwing of the power switch of the RF generator 1. Note that this power switch is the switch actually used to output power. In summary, what is required is a means for bringing the switches SW1 and SW2 to the OFF state immediately after an RF power has started to be applied to the input terminal T1 from the RF generator 1. Here, “immediately after” contains 0.1 second delay, so as to wait for the initial start-up of a load which is confirmed by ignition starting at the plasma chamber 3. The switches SW1 and SW2 may be brought to the OFF state either by detecting ignition at the plasma chamber 3, or by pre-setting a corresponding time (about 0.1 second). Generally speaking, the switches SW1 and SW2 may be brought to OFF immediately after the start-up of plasma after the load has started up to obtain an RF power (i.e. immediately after the initial start-up of the load).

If the coil L2, the capacitors C2, C3, C4, and the switches SW1, SW2 are removed from the above-stated structure, it will be the same as an automatic impedance matching network conventionally known. The variable capacitors VC1 and VC2 are respectively a vacuum capacitor. This vacuum capacitor has such a characteristic that if there is an air gap of 1 cm, it will not discharge even with application of a voltage of 100 KV.

The switches SW1 and SW2 are respectively a vacuum switch. When the input power is 1000 W, this vacuum switch is subjected to 1922V/0-p withstand voltage at maximum (the maximum withstand voltage of the vacuum switch is 3000V). Furthermore, the vacuum switch is subjected to an electric current of 1.3 A at maximum when the ignition power is 10 W. Therefore it is sufficient that if the vacuum switch allows about 2 A of electric current.

The circuit composed of the capacitor C2 and the coil L2 lowers the impedance. Other structures, such as an RF transformer, may be alternatively used in place of this circuit. This circuit has such a characteristic that, if the impedance at the terminal T1 is 50Ω, the impedance at the terminal T5 results in 10Ω. For example, the capacitor C2 is of 450 pF, and the coil L2 is of 220 nH. Furthermore, the capacitors C3 and C4 are of 2000 pF, for example. In addition, the coil L1 is of, for example, 600 nH including the L-portion of the variable capacitor VC2. The variable capacitor VC1 is of 160-200 pF, and the variable capacitor VC2 is of 273-667 pF, for example. The L-portion of the phase/amplitude detector 4 used for connection is of 150 nH.

The inductance L of the phase/amplitude detector 4 is 150 nH, and the phase/amplitude detector 4 transmits power without any substantial loss. The phase/amplitude detector 4 is of a conventional type, and is capable of detecting phase/amplitude and of informing the control unit 5 of the detected phase/amplitude.

ZP (R±jX) indicates a matching impedance of the plasma chamber 3, and RL indicates a real resistance. When an impedance looking into the RF generator 1 from the input terminals T1 and T2 is 50Ω, and an impedance looking into the impedance matching network 2 from the input terminals T1 and T2 is 50Ω, impedance matching is achieved at the input terminals T1 and T2. Here, an impedance ZR looking into the impedance matching network 2 from the output terminals T3 and T4 is 1Ω. The above-mentioned impedances of 50Ω are converted into 1.3Ω by means of the capacitors VC1 and VC2. Then, since the impedance ZR=RZ−Rm=1.3Ω−0.3Ω=1Ω, the real resistance Rm of the impedance matching network 2 results in 0.3Ω.

If an impedance looking into the plasma chamber 3 from the output terminals T3 and T4 (a resistance RL) is 1Ω, the impedance matching network 2 is matched in impedance to the plasma chamber 3. In this case, an imaginary number part of the impedance ZR and that of the impedance ZP do not have to be considered. This situation is called a conjugate matching.

If this impedance matching (50Ω-50Ω-1Ω-1Ω) is lost, the phase/amplitude detector 4 detects a change in phase and/or amplitude, and the control unit 5 controls rotation of the motors 6 and 7. In detail, when a change in phase occurs, the control unit 5 causes the motor 7 to rotate, to adjust the capacitor VC2. When a change in amplitude occurs, the control unit 5 causes the motor 6 to rotate, to adjust the capacitor VC1. In this way, impedance matching is again achieved. This is what a commercially-available automatic impedance matching network does. Needless to say, this explanation does not take into account the coil L2, the capacitors C2, C3, C4, and the switches SW1, SW2, which are newly added by the present invention.

The basic structure of the impedance matching network 2 is an impedance matching circuit that includes a phase-adjusting variable capacitor VC2 and an amplitude-adjusting variable capacitor VC1. The coil L1 is provided because the plasma chamber 3 is a capacitance load. If the plasma chamber 3 is a coil load, a capacitor should be provided instead of the coil L1. In a special case (e.g. when the plasma chamber 3 is a resistance load), neither a coil nor a capacitor is necessary.

Next, the following describes the functions performed by the capacitors C3, C4, and switches SW1, SW2, which are newly added for the purpose of improving the matching speed.

When there is no power output from the RF generator 1, the switches SW1 and SW2 are in the ON state. The plasma chamber 3 will ignite after receiving power via the impedance matching network 2 after the RF generator 1 is set ON. Before the ignition of the plasma chamber 3, the variable capacitors VC1 and VC2 do not function since the switch SW2 is kept in the ON state. After the switches SW1 and SW2 are brought to the OFF state after the ignition, the variable capacitors VC1 and VC2 start functioning, thereby immediately changing the plasma chamber 3 from the ignition state to the processing state. Note that the variable capacitors VC1 and VC2 have been pre-set to respective values that take into account values of the serial circuits either with the capacitor C3 or with the capacitor C4, so that desirable matching can be achieved immediately after these capacitors have started functioning.

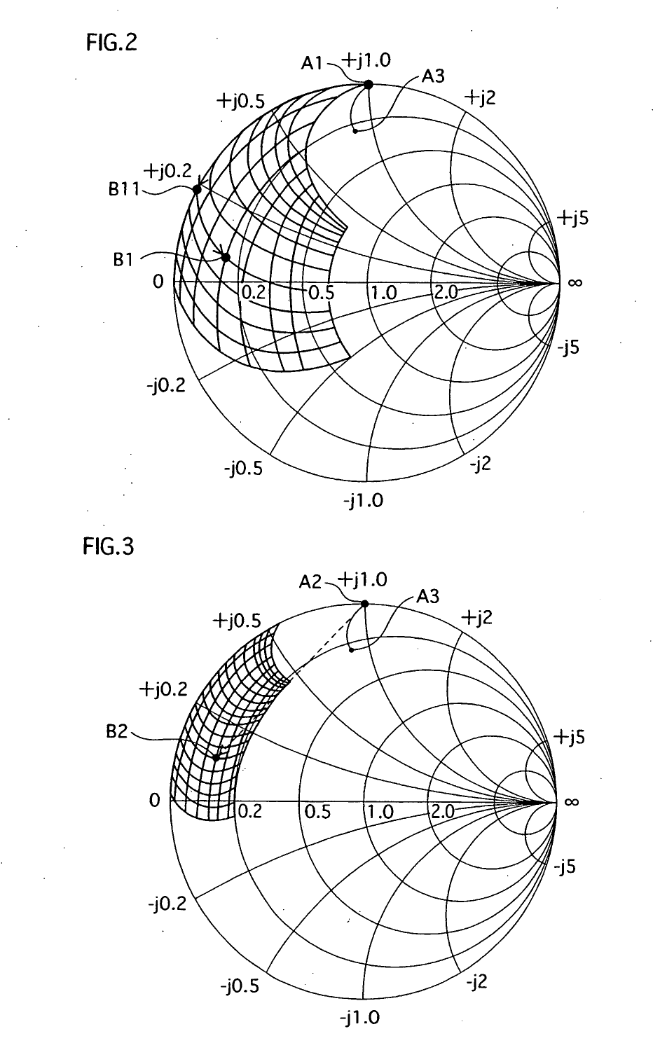

This situation is explained using the smith charts of FIGS. 2 and 3. In FIGS. 2 and 3, the meshed portions respectively represent a range in which impedance matching can be achieved by adjusting the variable capacitors VC1 and VC2. In addition, each circle represents a real number, whereas radial lines respectively represent an imaginary number.

FIG. 2 is a smith chart representing a conventional case. In FIG. 2, A1 represents impedance before ignition of the plasma chamber 3. Before generation of plasma in the plasma chamber 3, it indicates a capacitor of about 230 PF. If the RF generator 1 outputs a power of 1000 W for example, the plasma chamber 3 will be initially provided with a power of 5-10 W, to cause the plasma chamber 3 to ignite. Upon the ignition, the automatic impedance matching network starts operating, i.e. the values of the variable capacitors VC1 and VC2 change, to gradually increase the power supplied to the plasma chamber 3, in such an order as 50 W, 100 W, 300 W, and 500 W, for example. Finally, the power of nearly 770 W is supplied to the plasma chamber 3, to achieve the impedance matching (this state is represented by the processing position B1 in FIG. 2). Here, if only the variable capacitor VC2 is adjusted first, movement from the ignition position A1 to the point B11 is performed first. Then by adjusting the variable capacitor VC1, movement from the point B11 to the processing position B1 is performed. In reality, the variable capacitors VC1 and VC2 are simultaneously adjusted, and so a more complex path is taken than the stated path. The time required for impedance matching (i.e. until reaching to the processing position B1 from the ignition position A1) is 1-2 seconds, which is long.

Meanwhile, the case of the present invention is depicted in FIG. 3. As shown in FIG. 3, the plasma chamber 3 is ignited (Ignition position A2). Then immediately after the ignition of the plasma chamber 3, meaning that about 0.1 second after the ignition of the plasma chamber 3, the switches SW1 and SW2 are brought to OFF, so as to have the variable capacitors VC1 and VC2 to participate in the circuit operation. Specifically, the values of the VC1 and VC2 have been pre-set to be able to achieve impedance matching, and so in FIG. 3, the direct path to the processing position B2 is taken. Then after fine control of the variable capacitors VC1 and VC2, impedance matching will be achieved.

In this way, the present invention shortens the time required for achieving impedance matching. Accordingly, the present invention will cause hardly any damage on the products, which would occur before achievement of impedance matching.

Note that in FIG. 3, A2 is the ignition position when the variable capacitor VC1 takes the minimum value, and A3 is the ignition position when the variable capacitor VC1 takes the maximum value. Therefore the actual ignition position will be between A2 and A3.

Of course no problem would arise if the ignition occurs at the processing position B2. However at the processing position B2, power required for the ignition cannot be supplied to the plasma chamber 3. This is due to too large reflection (e.g. if there is an output of 100 W, the plasma chamber 3 will receive less than 1 W). If with such a little power, the plasma chamber 3 will not ignite.

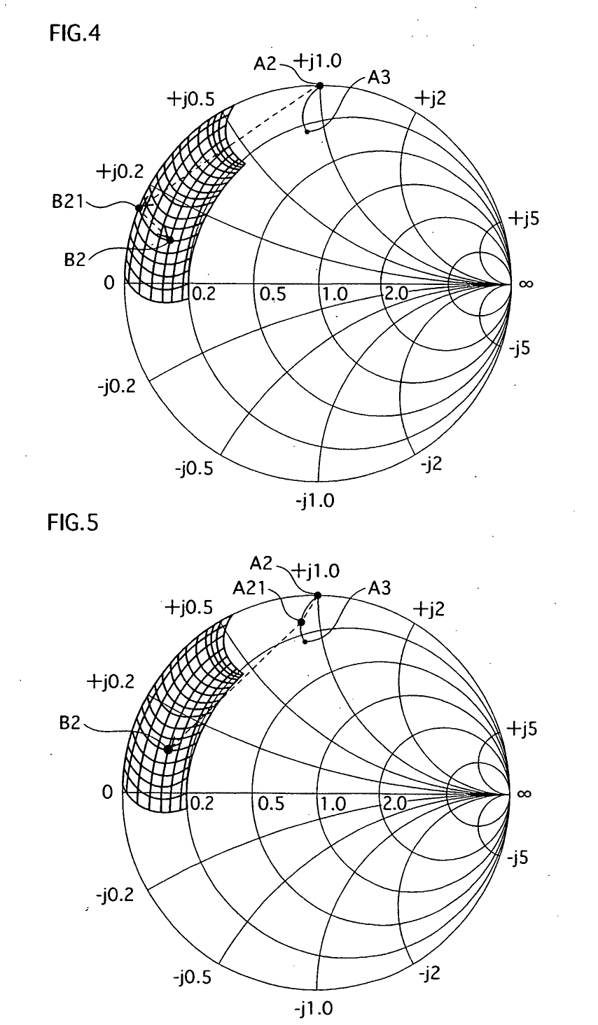

In FIGS. 1 and 3, the switches SW1 and SW2 are simultaneously brought to OFF. However it is also possible to delay any one of the switches. For example, if the switch SW2 is brought to OFF earlier than the switch SW1, the path will be from the ignition position A2 to the point B21, to eventually reach the processing position B2 (see FIG. 4). On the contrary, if the switch SW1 is brought to OFF earlier than the switch SW2, then the path will be from A2 to the point A21, to reach the processing position (see FIG. 5).

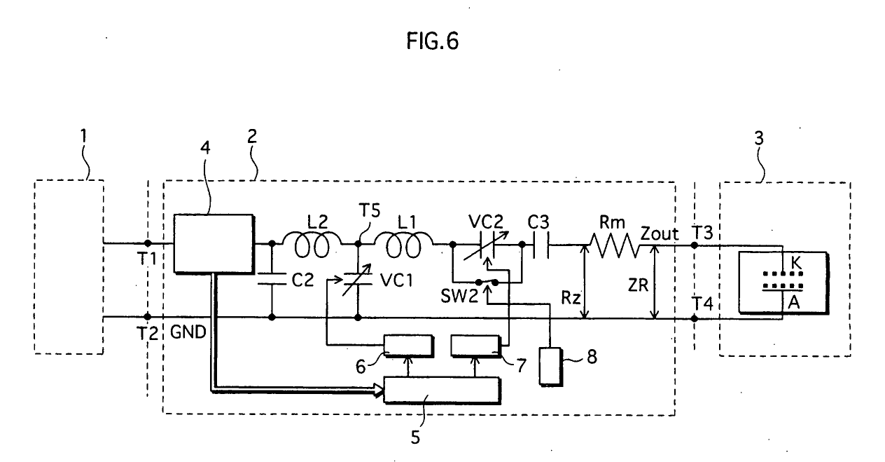

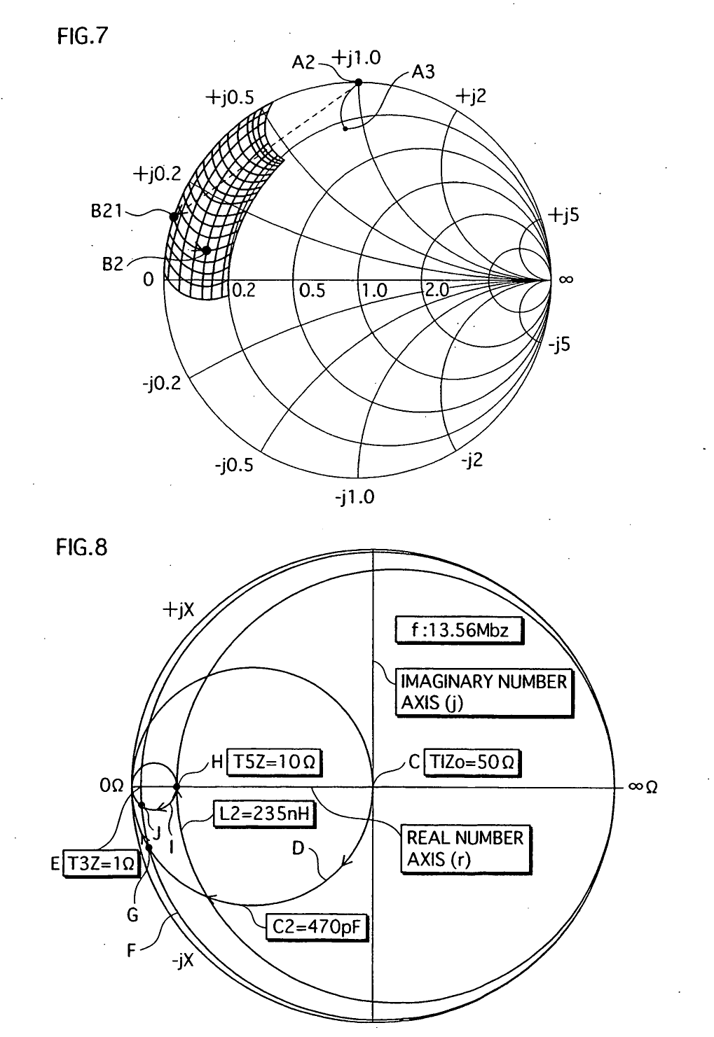

It is also possible to structure a circuit having the switch SW2 and the capacitor C3, and without the switch SW1 and the capacitor C4, as shown in FIG. 6. This circuit will produce a path from the ignition point A2 to the point B2 (FIG. 7), and eventually to the processing position by means of the adjustment of the variable capacitor VC1 as in the conventional case. In this case, movement from the ignition position A2 to the point B21 becomes fast. However adjustment of the variable capacitor VC1 takes long. Therefore overall, a level of improvement in this case is smaller than the case of FIG. 1, however this case still exhibits improvement when compared to conventional cases. In the same manner, it is also possible to structure a circuit having the switch SW1 and the capacitor C4, and without the switch SW2 and the capacitor C3.

Next, the following describes functions performed by the capacitor C2 and the coil L2, which are provided for improving the level of matching.

The efficiency η is calculated as 76.92% (i.e. η=ZR/(Rm+ZR)=1/(0.3+1)=0.76927=76.92%). Therefore, when Pf=1000 W, the transfer power will be 769.2 W.

When power of 1000 W is supplied from the RF generator 1, the level of matching is better in the case where the reflection is 1 W than in the case where the reflection is 10 W. An effective input power is obtained by subtracting a reflected wave power from an input power. Therefore, if the reflection is 10 W, the impedance matching network 2 will actually receive a power of 990 W. In such a case, however, the condition of “the matching impedance ZR=load RL(1Ω)” does not hold anymore, because of the deviation of ZR from RL.

When ZR deviates from 1Ω (or jX deviates with ZR remaining at 1Ω), since the efficiency of the impedance matching network is η=ZR/(Rm+ZR), there is a possibility that ZR largely deviates if the reflected wave power is large. This state is represented by uncertainty of the matching impedance ZR. The efficiency η is also susceptible to fluctuate.

When processing wafers for manufacturing semiconductor products in three stages on condition that the reflected wave power Pr=10 W, the fluctuation during the three stages is occasionally in the range of 724.4-794.9 W (with the difference in the range of −44.8 W to 25.7 W). Therefore, variations of wafers are possible. Here, when the progressive wave power is Pf and the reflected wave power is Pr, the voltage standing wave ratio (VSWR) can be calculated as follows, VSWR=1+(Pr/Pf)2/1−(Pr/Pf)2. Therefore, when Pf=1000 w and Pr=1 W, VSWR=1.0653:1. This means that when the impedance ZR′ (ZR7′) in impedance mismatch is either 1/1.0653 of the case where ZR is 1Ω, or 1.0653 times the case where ZR is 1Ω, where ZR indicates a non-reflected wave power matching impedance. That is, the impedance ZR′ in impedance mismatch in this case is in the range of 0.9387Ω to 1.0653Ω.

When there is 1 W reflected wave power when the input power to the impedance matching network is 1000 W, it indicates that the impedance ZR′ in impedance mismatch is generated when the effective input power is 999 W. Therefore, η′=ZR′/(Rm+ZR′), and so the value of η′ is different from the former-mentioned value of η=76.92% which is at the time of non-reflected wave power matching impedance.

The efficiency of the impedance matching network, when there is Pr=1 W (0.1%) reflected wave power, is calculated as follows for ZR-Low:

L−η=0.9387/(0.3+0.9387)=0.7578=75.78%(−1.85%);

and is calculated as follows for ZR-Hig:

H−η(L−η)=1.0653/(0.3+1.0653)=0.7803=78.03%(+1.33%).

Therefore, when there is 1 W reflected wave power, uncertainty occurs in the range calculated as follows:

999 W×0.7578=757.0 W to 999 W×0.7803=779.5 W

When Pf=1000 W:Pr=10 W, VSWR=1.2222:1. Which is to say, when the impedance ZR″ in impedance mismatch is either 1/1.2222 of the case where ZR is 1Ω, or 1.2222 times the case where ZR is 1Ω, where ZR indicates a non-reflected wave power matching impedance. That is, the impedance ZR″ in impedance mismatch in this case is in the range of 0.8182Ω to 1.2222Ω.

When there is 10 W reflected wave power when the input power to the impedance matching network is 1000 W, it indicates that the impedance ZR″ in impedance mismatch is generated when the effective input power is 990 W. Therefore, η″=ZR″/(Rm+ZR″), and so the value of η″ is different from the former-mentioned value of η=76.92% which is at the time of non-reflected wave power matching impedance.

The efficiency of the impedance matching network, when there is Pr=10 W(1%) reflected wave power, is calculated as follows for ZR-Low:

L−η=0.8182/(0.3+0.8182)=0.7317=73.17%(−5.83%);

and is calculated as follows for ZR-Hig:

H−η(L−η)=1.2222/(0.3+1.2222)=0.8029=80.29%(+3.34%).

Therefore, when there is 10 W reflected wave power, uncertainty occurs in the range calculated as follows:

990 W×0.7317=724.4 W to 990 W×0.8029=794.9 W

Therefore, in relation to the plasma processing supply power, when Pr=1 W(0.1%), uncertainty in the range of −1.85 to 1.33% occurs. Whereas when Pr=10 W(1%), uncertainty in the range of −5.83 to 3.34% occurs.

Here, suppose that the impedance of the terminal T1 is 50Ω, and the impedance of the terminal T3 is 1Ω, in a structure in which the capacitor C2 and the coil L2 are eliminated from FIG. 1. Then if impedance matching is attempted by changing the value of the variable capacitor VC1, not only the real resistance portion that should originally change, but also the imaginary number portion change. This situation is detailed using the smith chart of FIG. 8.

In FIG. 8, the horizontal axis corresponds to a real number portion, with the left end being 0Ω and the right end being ∞Ω. The vertical axis corresponds to an imaginary number portion. By changing the variable capacitor VC1 from the point C (the terminal T1 in FIG. 1), the value of the variable capacitor VC1 changes along the arc D. The impedance matching is achieved at the intersection (i.e. point G) between the arc F of 1Ω passing the point E (the terminal T3 in FIG. 1) and the arc D. As can be seen from this movement, the change in value does not move along the axis representing the real number portion, but moves along the arc D, meaning that not only the real number portion but also the imaginary number portion change. In reality, at the point G, the movement does not stop because of impedance matching, but induces hunting that centers on the point G. Hunting is a phenomenon in which the value sways back and forth the matching value. Such hunting causes matching achievement to take long, and so is not favorable in control point of view.

Looking at the situation where hunting occurs centering on the point G, the hunting occurs along the arc D, and so the change in the vertical direction (i.e. the direction of the imaginary number axis) is large, compared to the change in the horizontal direction (i.e. the direction of the real number axis). The larger change in the vertical direction indicates large reflection. Therefore, it is desirable to decrease the change in the imaginary number axis direction.

For improvement in this point, the present invention provides a circuit composed of the capacitor C2 and the coil L2. The above-described circuit is designed to convert impedance. In the present embodiment, if the impedance at the terminal T1 is assumed to be 50Ω, the circuit performs conversion so that impedance at the terminal T5 is 10Ω.

If 50Ω is converted to 10Ω, the following will occur. The point H in FIG. 8 corresponds to 10Ω. Therefore by changing the variable capacitor VC1, the value changes along the arc I, toward the matching point J. As can be seen by comparing the point G and the point J, the change at the point J in the imaginary number axis direction is small than at the point G, meaning a smaller reflection at the point J than at the point G.

The following describes this from a different point of view.

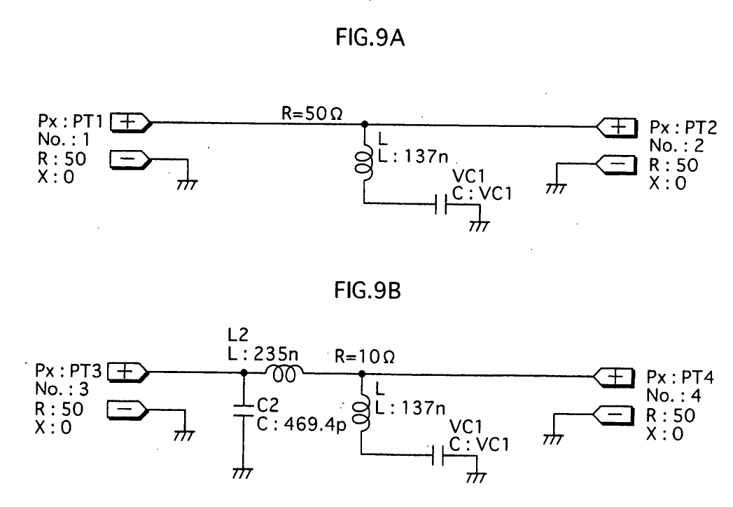

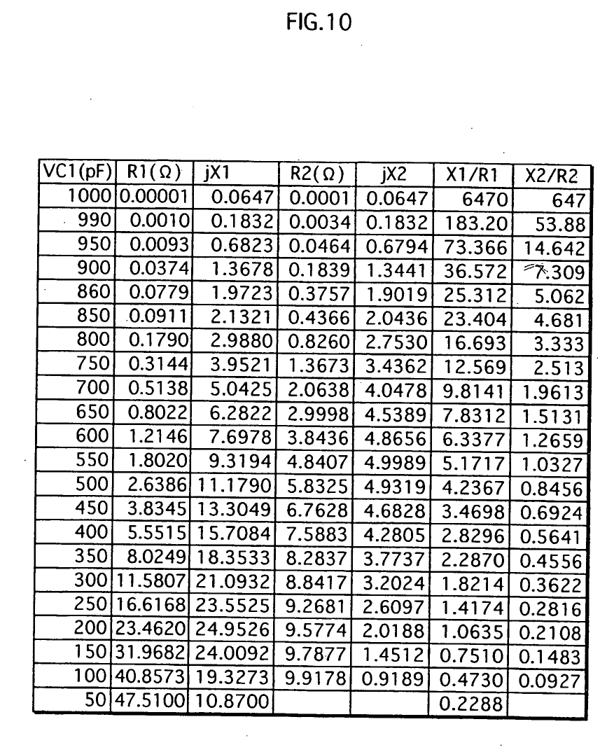

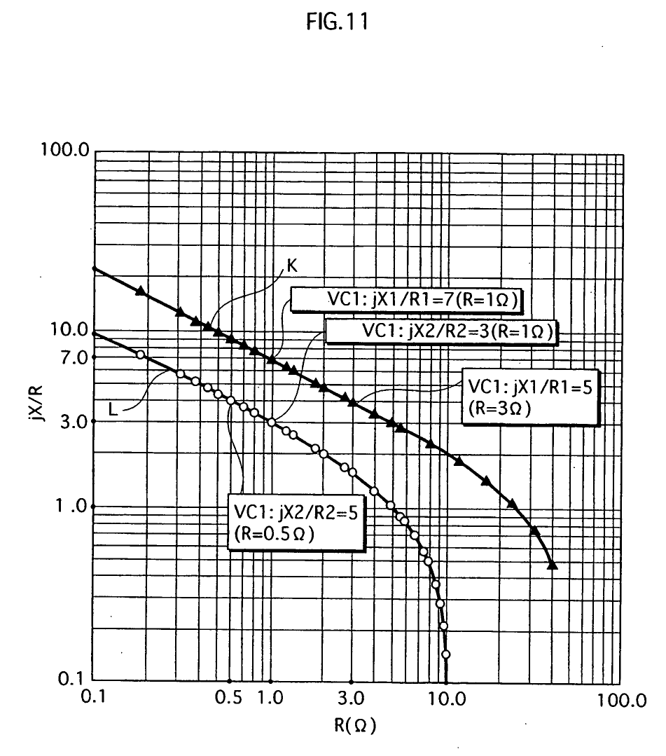

FIG. 9A shows a conventional circuit without the capacitor C2 and the coil L2. FIG. 9B shows a circuit of the present invention that has the capacitor C2 and the coil L2. Here, L represents an inductance of the joint portion of the variable capacitor VC1. The table of FIG. 10 shows a result of simulation conducted using the S parameter analysis software and using a signal of 13.56 MHz. FIG. 10 shows calculated values for R1 and jX1 for the conventional circuit (FIG. 9A), and values for R2 and jX2 for the circuit of the present invention (FIG. 9B), for each type of the variable capacitor VC1 generated from 50 pF to 1000 pF in 50 pF increments. FIG. 10 also shows calculated values of X1/R1 and X2/R2 for each type of the variable capacitor VC1. FIG. 11 shows graphs created based on FIG. 10. In FIG. 11, K represents a graph for the conventional circuit shown in FIG. 9A, and L represents a graph for the circuit of the present invention shown in FIG. 9B. As can be understood by these graphs, when R=1Ω, jX is 7 times R in the conventional case, whereas jX is 3 times R in the present invention. This exhibits a smaller fluctuation of jX in the present invention. In the same magnification (jX/R), the value of R (targeted matching value) is 3Ω for the conventional circuit, and 0.5Ω for the circuit of the present invention. This exhibits a more favorable matching level in the present invention.

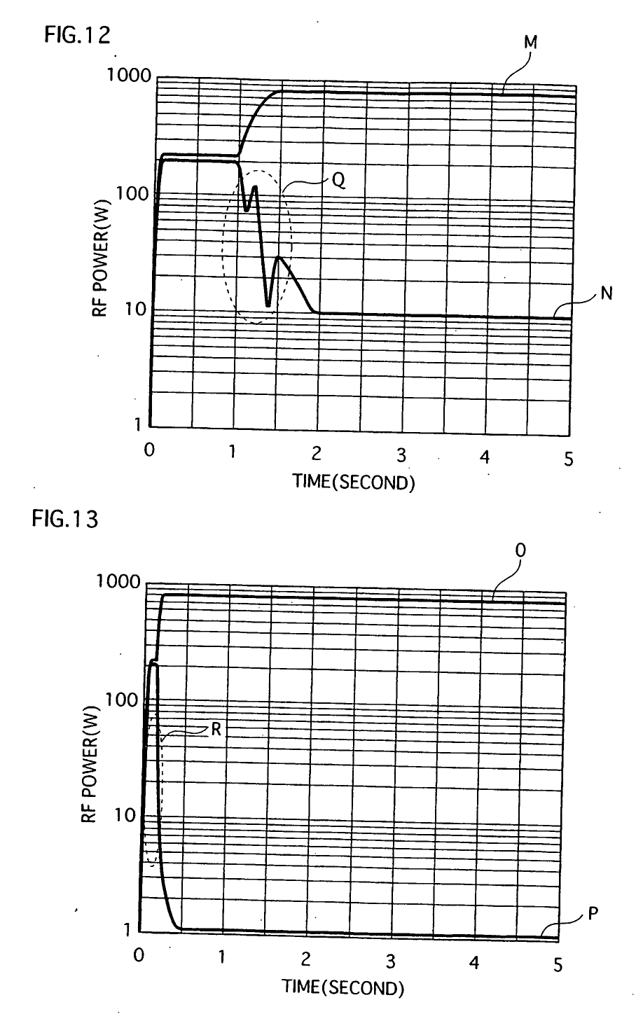

This is further detailed using FIG. 12.

FIG. 12 shows data for a conventional circuit that does not have a capacitor C2, a coil L2, capacitors C3, C4, and switches SW1, SW2. FIG. 13 shows data for the circuit of the present invention. In FIGS. 12 and 13, M and O represent a power outputted from the RG generator 1, respectively, and N and P represent a reflected power returned to the RF generator 1, respectively.

In FIG. 12, the RF generator 1 outputs power in 0 second. Immediately thereafter, the plasma chamber ignites, and the impedance matching network 2 starts operating, to cause moving from the ignition point R(0Ω), which is low, towards the matching point. When the reflected power is large, the output power is maintained to about 200 wattages (20% of the power rating) for the purpose of protecting the RF generator 1. At this stage, most power is reflected. As the matching level increases, output from the RF generator increases as well, and reflected power starts to decrease.

In this process, hunting occurs because the matching starts from the low ignition point R, as mentioned above. This corresponds to the portion Q in FIG. 12. The drawing shows one example of such hunting, which sways relatively large. However there are cases where the swaying is smaller and longer. The remaining reflected power achieves matching at the point where the reflection is 10 wattages (1%) by stopping the variable capacitors VC1 and VC2 according to the amount of hunting and the control quality. The movement described so far relates to the conventional apparatus. Next, the data for the present invention is described. As shown in FIG. 13, after ignition of the plasma chamber 3 after the RF generator has outputted power, the switches SW1 and SW2 are brought to the OFF state and the matching is achieved immediately. Then after passing the R portion in FIG. 13, the variable capacitors VC1 and VC2 are made to stop with remaining reflection of 1 wattage for example (0.1%). When the reflected power is 5 wattages, the matching is achieved but the variable capacitors VC1 and VC2 will be stopped at the remaining reflection of 1 wattage. In the example of the drawing, the R portion is depicted as if hunting is not occurring. However in reality, small sways are caused. In this way, the present invention has an improved matching speed and favorable matching (i.e. smaller reflected power).

### INDUSTRIAL APPLICABILITY

The present invention is particularly advantageous as a plasma processing apparatus used in manufacturing semiconductor products, and as an impedance matching network used for the plasma processing apparatus.

1. An impedance matching network comprising:
an amplitude-adjusting variable capacitor and a phase-adjusting variable capacitor that are positioned between an input terminal and an output terminal, matching being achieved by adjustment of values of the variable capacitors;
a first capacitor connected in series to one of the variable capacitors;
a first switch connected in parallel to the one of the variable capacitors; and
a unit operable to a) keep the first switch to an ON state while the input terminal does not receive RF power, and b) bring the first switch to an OFF state immediately after an initial start-up of a load connected to the output terminal after the input terminal has started to receive RF power.

2. The impedance matching network of claim 1, further comprising:
a second capacitor connected in series to the other of the variable capacitors;
a second switch connected in parallel to the other of the variable capacitors; and
a unit operable to a) keep the second switch to an ON state while the input terminal does not receive RF power, and b) bring the second switch to an OFF state immediately after the initial start-up of the load connected to the output terminal after the input terminal has started to receive RF power.

3. The impedance matching network of claim 1, comprising
a circuit operable to lower impedance, the circuit being positioned between the input terminal and an impedance matching circuit that is mainly composed of the variable capacitors.

4. The impedance matching network of claim 2, wherein
the first switch and the second switch are simultaneously brought to an OFF state.

5. A plasma processing apparatus comprising:
an impedance matching network including an amplitude-adjusting variable capacitor and a phase-adjusting variable capacitor that are positioned between an input terminal and an output terminal;
an RF generator connected to the input terminal; and
a plasma chamber connected, as a load, to the output terminal, matching between the RF generator and the plasma chamber being achieved by adjustment of values of the variable capacitors, wherein
the impedance matching network includes:
a first capacitor connected in series to one of the variable capacitors;
a first switch connected in parallel to the one of the variable capacitors; and
a unit operable to a) keep the first switch to an ON state while the input terminal does not receive RF power, and b) bring the first switch to an OFF state immediately after ignition of the plasma chamber after the input terminal has started to receive RF power.

6. The plasma processing apparatus of claim 5, further comprising:
a second capacitor connected in series to the other of the variable capacitors;
a second switch connected in parallel to the other of the variable capacitors; and
a unit operable to a) keep the second switch to an ON state while the input terminal does not receive RF power, and b) bring the second switch to an OFF state immediately after the ignition of the plasma chamber after the input terminal has started to receive RF power.

7. The plasma processing apparatus of claim 5, comprising:
a circuit operable to lower impedance, the circuit being positioned between the input terminal and an impedance matching circuit that is mainly composed of the variable capacitors.

8. The plasma processing apparatus of claim 6,
the first switch and the second switch are simultaneously brought to an OFF state.

9. The plasma processing apparatus of claim 5, wherein
the variable capacitors are pre-set to respective values before application of RF power to the input terminal, the values being such that impedance matching between the RF generator and the plasma chamber is achieved.
